(19) United States
(12) Patent Application Publication
(10) Pub. No.: US 2026/0237956 A1
(43) Pub. Date: Aug. 13, 2026

(54) LASER CHAMBER PREIONIZER HAVING ACOUSTIC SCATTERING SURFACE

(71) Applicant: Cymer, LLC, San Diego, CA (US)

(72) Inventor: Thomas Dickson Steiger, San Diego, CA (US)

(21) Appl. No.: 19/164,348

(22) PCT Filed: Mar. 21, 2024
(86) PCT No.: PCT/IB2024/052731

§ 371 Date: Sep. 11, 2025

Related U.S. Application Data
(60) Provisional application No. 63/455,476, filed on Mar. 29, 2023.
(60) Provisional application No. 63/560,973, filed on Mar. 4, 2024.

(51) Int. Cl. H01S 3/036

(52) U.S. Cl. CPC H01S 3/036

(57) ABSTRACT

An apparatus for generating laser radiation from discharges in a discharge chamber in which the discharges produce acoustic waves which would disrupt operation of the apparatus at certain repetition rates if reflected back to their origin in which the surface of a preionizer tube positioned in the discharge chamber is provided with acoustic scattering features which scatter acoustic waves impinging on the preionizer tube surface. The preionizer tube may also be configured to have a transverse cross section that presents an angled surface to the region in which discharges are produced.

### CROSS-REFERENCE TO RELATED APPLICATIONS

This application claims priority of U.S. application No. 63/455,476, which was filed on Mar. 29, 2023, titled LASER CHAMBER PREIONIZER HAVING ACOUSTIC SCATTERING SURFACE, and U.S. application No. 63/560,973, which was filed on Mar. 4, 2024, titled LASER CHAMBER PREIONIZER HAVING ACOUSTIC SCATTERING SURFACE, which are incorporated herein in its entirety by reference.

### FIELD

The disclosed subject matter relates to laser discharge chambers in which discharges in a discharge region produce laser radiation and also produce acoustic disturbances which may be undesirably reflected back to the discharge region.

### BACKGROUND

Photolithography is a process by which semiconductor circuitry is patterned on a substrate such as a silicon wafer. A photolithography radiation source provides the deep ultraviolet (DUV) radiation (wavelengths in a range of about 100 nanometers (nm) to about 400 nm) used to expose a photoresist on the wafer. Often, the radiation source is a laser source and the radiation is a pulsed laser beam. The radiation beam is passed through a beam delivery unit, then a reticle or a mask, and then projected onto a silicon wafer coated with photoresist. In this way, a chip design is patterned onto a photoresist that is then etched and cleaned.

In many systems that produce a laser beam (such as a laser generator) or employ a laser beam (such as a photolithography system), there is an optical train that includes one or more optical components (such as mirrors, gratings, prisms, optical switches, filters, etc.). Optical components in the optical train may, wholly or partially, reflect, process, filter, modify, focus, expand, etc. the laser beam to obtain one or more desired laser beam outputs.

In such systems the laser beam is produced by causing discharges in an interelectrode discharge region of one or more laser discharge chambers. One challenge in the design and use of these systems is that the discharge which produces the laser radiation also generates strong acoustic waves inside the discharge region. These acoustic waves create gas density modulations that propagate within the laser discharge chamber. Surfaces in the laser discharge chamber may reflect these acoustic waves back into the discharge region and adversely affect the laser's performance. In particular these reflected waves may result in a round trip time-of-flight resonance depending on the inter-pulse delay or discharge repetition rate at which the laser system is operated.

It would be advantageous to mitigate the adverse effects of these acoustic disturbances. It is in this context that the need for the subject matter of the present disclosure arises.

### SUMMARY

The following presents a succinct summary of one or more embodiments in order to promote a basic understanding of the presently disclosed subject matter. This summary is not an extensive overview of all contemplated embodiments and is not intended to identify as key or critical any elements of any embodiments nor delineate the scope of any or all embodiments. Its sole purpose is to present some concepts relating to one or more embodiments in a streamlined form as a prelude to the more detailed description that is presented later.

According to an aspect of an embodiment there is disclosed a preionizer for a laser system, the preionizer comprising a tube configured as a generally cylindrical hollow tube extending axially in a first direction and having a tube wall with an outer surface, at least a portion of the outer surface being provided with a plurality of acoustic scattering features and an electrode positioned at least partially within the tube.

The tube may comprise a dielectric material. The acoustic scattering features may have a depth into the tube wall greater than one half the nominal thickness of the tube wall.

In cases in which the laser system operates at 6 kHz the acoustic scattering features may have depths into the tube wall of at least 0.063 inches.

The laser system may be configured to generate a discharge in a discharge region having a height H and a width W and the depth of the acoustic scattering features into the tube wall may be in a range between ¼ H and ¼ W, inclusive.

The laser system may be configured to generate a discharge in a discharge region and the acoustic scattering features may be provided on at least a portion of the outer surface arranged to face the discharge area. The acoustic scattering features may be provided on substantially all of the outer surface.

The acoustic scattering features may be made by molding the acoustic scattering features into the at least a portion of the outer surface.

The plurality of acoustic scattering features may be arranged in an array provided on the at least a portion of the outer surface. The array may be aperiodic.

Nearest ones of the plurality of acoustic scattering features may be spaced apart edge-to-edge by distances in a range from 0.01 inches to 0.5 inches. The acoustic scattering features may be arranged to have a density in a range of 3 acoustic scattering features per square inch to 100 acoustic scattering features per square inch. The plurality of acoustic scattering features may include acoustic scattering features respectively having areas in a range of 0.1 square inches to 0.5 square inches. The plurality of acoustic scattering features may collectively have a percent coverage of the outer surface in a range of 10 percent to 100 percent.

According to another aspect of an embodiment there is disclosed a preionizer for an excimer laser, the preionizer comprising a tube body having a tube wall, the tube wall having an external surface, a plurality of baffles provided on an acoustic scattering surface of the external surface, the acoustic scattering surface extending lengthways along a length of the tube body, each of the baffles being arranged and dimensioned to scatter acoustic reflections from the acoustic scattering surface, and an electrode positioned at least partially within the tube body.

The tube wall may comprise a dielectric material. The baffles may have a depth into the tube wall that is greater than one half the thickness of the tube wall. The excimer laser may operate at 6 kHz in which case the baffles have depths into the tube wall of at least 0.063 inches.

The excimer laser may be configured to generate a discharge in a discharge region having a height H and a width W and a depth of the baffles into the tube wall may be in a range between ¼ H and ¼ L, inclusive.

The excimer laser may be configured to generate a discharge in a discharge region and the acoustic scattering surface may comprise a portion of the external surface facing the discharge area. The acoustic scattering surface may comprise substantially all of the external surface.

The acoustic scattering surface may be made by molding the baffles into the tube wall.

The acoustic scattering surface may comprise an array of baffles provided on the external surface. The array may be aperiodic. The plurality of baffles may be arranged to have a density in a range of 3 baffles per square inch to 100 baffles per square inch. The plurality of baffles may include baffles respectively having areas in a range of 0.1 square inches to 0.5 square inches.

The baffles may have a nearest neighbor edge-to-edge spacing in a range of 0.01 inches to 0.5 inches. The plurality of baffles may cover 10 percent to 100 percent of the external surface.

According to another aspect of an embodiment there is disclosed a discharge chamber for a laser system, the discharge chamber comprising a first electrode having a first electrode discharge surface, a second electrode having a second electrode discharge surface, the first electrode discharge surface being arranged facing and spaced away from the second electrode discharge surface to define a discharge gap, and a preionizer including a preionizer tube extending laterally adjacent the first electrode, a surface of the preionizer tube facing the discharge gap being provided with a plurality of acoustic scattering features dimensioned and arranged to scatter acoustic waves from the discharge gap.

The preionizer tube may comprise a dielectric material. The acoustic scattering features may have a depth into the preionizer tube facing the discharge gap, that is greater than one half the nominal thickness of a wall of the preionizer tube. The discharge chamber may operate at 6 kHz and the acoustic scattering features may have depths into the preionizer tube of at least 0.063 inches.

The discharge chamber may be configured to generate a discharge in a discharge region having a height H and a width W and a depth of the acoustic scattering features into the preionizer tube may be in a range between ¼ H and ¼ W, inclusive.

The acoustic scattering surface may be made by molding the acoustic scattering features into a wall of the preionizer tube.

The acoustic scattering surface may comprise an array of acoustic scattering features provided on the surface of the preionizer tube facing the discharge gap. The array may be aperiodic.

The respective acoustic scattering features may be spaced apart edge-to-edge from a nearest acoustic scattering structure by distances in a range from 0.01 inches to 0.5 inches. The acoustic scattering features may be arranged to have a density on the surface of the preionizer tube facing the discharge gap in a range of 3 acoustic scattering features per square inch to 100 acoustic scattering features per square inch. The plurality of acoustic scattering features may include acoustic scattering features respectively having areas in a range of 0.1 square inches to 0.5 square inches. The acoustic scattering features may cover about 10 percent to 100 percent of the surface of the preionizer tube facing the discharge gap.

Further embodiments, features, and advantages of the subject matter of the present disclosure, as well as the structure and operation of the various embodiments, are described in detail below with reference to the accompanying drawings.

### BRIEF DESCRIPTION OF THE DRAWINGS

The accompanying drawings, which are incorporated herein and form part of the specification, illustrate the presently disclosed subject matter and, together with the description, further serve to explain the principles of the presently disclosed subject matter and to enable a person skilled in the relevant art(s) to make and use the presently disclosed subject matter.

FIG. 1 is a schematic diagram, not to scale, of an overall broad conception of a photolithography system.

FIG. 2 is a schematic diagram, not to scale, of an overall broad conception of an illumination system such as might be used in the photolithography system of FIG. 1.

FIG. 3 is a cross section, not to scale, of a discharge chamber such as might be used in the illumination system of FIG. 2.

FIG. 4 is a cross section, not to scale, of a portion of the discharge chamber of FIG. 3.

FIG. 5 is a perspective view, not to scale, of an arrangement of components in the discharge chamber of FIG. 3.

FIG. 6A is a cross section of part of the length of a preionizer system and a discharge in a discharge region.

FIG. 6B is an end-on cross section of the preionizer system and discharge of FIG. 6A.

FIG. 7 is a diagram, not to scale, of a portion of a wall for a preionizer tube of a preionizer system according to an aspect of an embodiment.

FIG. 8 is a projection of a portion of an exterior surface of a preionizer tube wall provided with an arrangement of acoustic scattering features to create an acoustic scattering surface according to an aspect of an embodiment.

FIG. 9 is a projection of a portion of an exterior surface of a preionizer tube wall provided with another arrangement of acoustic scattering features to create an acoustic scattering surface according to an aspect of an embodiment.

FIG. 10 is a side view of a preionizer tube with acoustic scattering features according to an aspect of an embodiment.

FIG. 11 is a perspective view of the preionizer tube of FIG. 10.

FIGS. 12A-12D are side views of examples of embodiments of acoustic scattering features according to aspects of embodiments.

FIG. 13A is a side view cross section of a preionizer according to an aspect of an embodiment.

FIG. 13B is an end-on view of the preionizer of FIG. 13A.

FIG. 14A is a side view cross section of a preionizer tube according to another aspect of an embodiment.

FIG. 14B is a side view cross section of a preionizer tube according to another aspect of an embodiment.

FIG. 14C is a side view cross section of a preionizer tube according to another aspect of an embodiment.

FIG. 15 is a side view cross section of a preionizer tube according to another aspect of an embodiment.

Further features and advantages of the presently disclosed subject matter, as well as the structure and operation of various embodiments of the presently disclosed subject matter, are described in detail below with reference to the accompanying drawings. It is noted that the scope of the presently disclosed subject matter is not limited to the specific embodiments described herein. Such embodiments are presented herein for illustrative purposes only. Additional embodiments will be apparent to persons skilled in the relevant art based on the teachings presented herein.

### DETAILED DESCRIPTION

Various embodiments are now described with reference to the drawings, wherein like reference numerals are used to refer to like elements throughout. In the following description, for purposes of explanation, numerous specific details are set forth in order to promote a thorough understanding of one or more embodiments. It may be evident in some or all instances, however, that any embodiment described below can be practiced without adopting the specific design details associated with it below. In other instances, well-known structures and devices are shown in block diagram form in order to facilitate description of one or more embodiments. This summary is not an extensive overview of all contemplated embodiments and is not intended to single out as key or critical any elements of any embodiments nor delineate the scope of any or all embodiments.

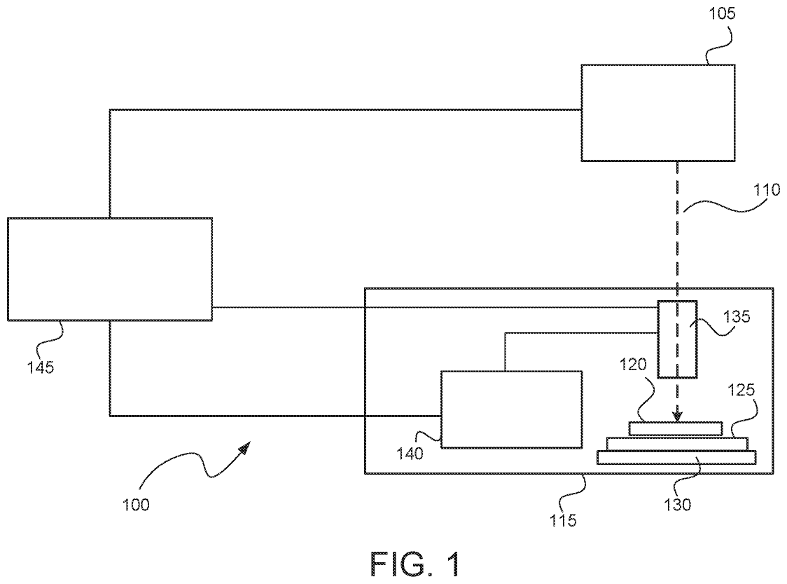

Systems such as those described herein may render benefits in a wide range of applications and implementations. For the sake of having a specific nonlimiting example to facilitate description, one such application is in semiconductor photolithography. FIG. 1 shows a photolithography system 100 that includes an illumination system 105. As described more fully below, the illumination system 105 includes a radiation source that produces a pulsed radiation beam 110 and directs it to a photolithography exposure apparatus 115 such as a scanner that patterns microelectronic features on a wafer 120. The wafer 120 is placed on a wafer table 125 constructed to hold wafer 120 and connected to a positioner 130 configured to accurately position the wafer 120 in accordance with certain parameters.

The pulsed radiation beam 110 may have a wavelength in the DUV range, for example, with a wavelength of 248 nanometers (nm) or 193 nm. The scanner 115 includes an optical arrangement 135 having, for example, one or more condenser lenses, a mask, and an objective arrangement. The mask is movable along one or more directions, such as along an optical axis of the pulsed radiation beam 110 or in a plane that is perpendicular to the optical axis. The objective arrangement includes a projection lens and enables an image transfer to occur from the mask to photoresist on the wafer 120. The illumination system 105 adjusts the range of angles for the pulsed radiation beam 110 impinging on the mask. The illumination system 105 also homogenizes (makes uniform) the intensity distribution of the pulsed radiation beam 110 across the mask.

The scanner 115 can include, among other features, a lithography controller 140 that controls how layers are printed on the wafer 120. The lithography controller 140 may include a memory that stores information such as process recipes that determine the parameters of the beam including a length of the exposure on the wafer 120 based on, for example, the mask used, as well as other factors that affect exposure. During lithography, a burst of pulses of the pulsed radiation beam 110 illuminates the same area of the wafer 120 to constitute an illumination dose.

The photolithography system 100 also preferably includes a control system 145. In general, the control system 145 includes one or more of digital electronic circuitry, computer hardware, firmware, and software. The control system 145 can be centralized or be partially or wholly distributed throughout the photolithography system 100.

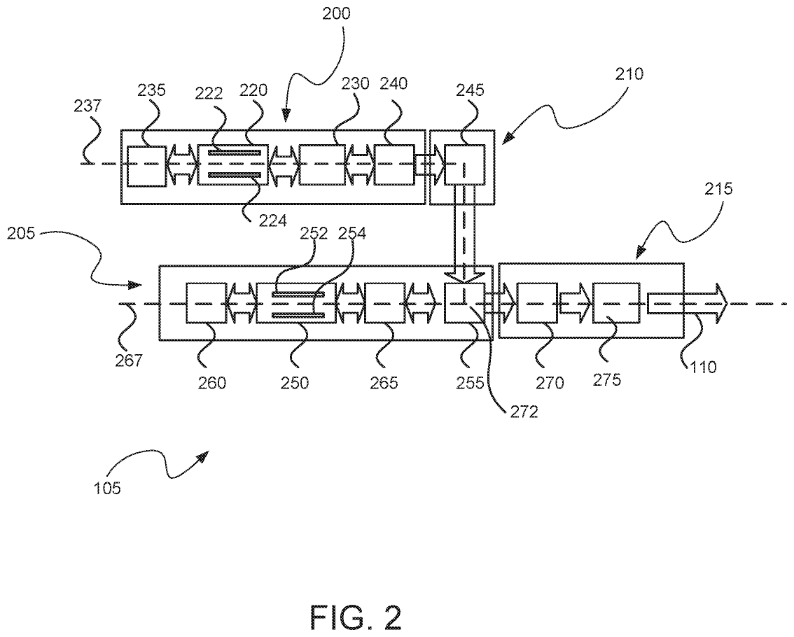

FIG. 2 shows a pulsed laser source that produces a pulsed laser beam as the radiation beam 110 as an example of an illumination system 105. FIG. 2 shows a two-chamber laser system as a nonlimiting example but it will be understood that the principles explained herein are equally applicable to a single chamber laser system or a laser system having more than two chambers. The gas discharge laser system may include, e.g., a solid state or gas discharge master oscillator (“MO”) seed laser system 200, an amplification stage, e.g., a power ring amplifier (“PRA”) stage 205, relay optics 210, and laser system output subsystem 215. The seed system 200 may include, e.g., an MO chamber 220 which includes a pair of electrodes 222 and 224.

The MO seed laser system 200 may also include a master oscillator output coupler (“MO OC”) 230, which may comprise a partially reflective mirror, forming an MO discharge chamber 220 with an oscillator cavity, defined in part by a reflective grating (not shown) in a line narrowing module (“LNM”) 235, that oscillates to form the seed laser output pulse. The MO seed laser system 200 may also include a line-center analysis module (“LAM”) 240. A MO wavefront engineering box (“WEB”) 245 may serve to redirect the output of the MO seed laser system 200 toward the amplification stage 205, and may include, e.g., a multi prism beam expander (not shown) and an optical delay path (not shown). The beam path through the LNM 235, the MO discharge chamber 220, the MO OC 230, and the LAM 240 defines an optical axis 237 for each of these components.

The amplification stage 205 may include, e.g., a PRA discharge chamber 250, which also may be an oscillator, e.g., formed by seed beam injection and output coupling optics (not shown) that may be incorporated into a PRA WEB 255. The beam may be redirected back through the gain medium in the PRA discharge chamber 250 by a beam reverser (“BR”) 260. The PRA WEB 255 may incorporate a partially reflective input/output coupler (not shown) and a maximally reflective mirror for the nominal operating wavelength (e.g., at around 193 nm for an ArF system) and one or more prisms. The PRA discharge chamber 250 may also include a pair of electrodes 252 and 254.

A bandwidth analysis module (“BAM”) 265 may receive the output laser radiation beam of pulses from PRA discharge chamber 250 and pick off a portion of the radiation beam for metrology purposes, e.g., to measure the output bandwidth and pulse energy. The laser output radiation beam of pulses then passes through the PRA WEB 255 to an optical pulse stretcher (“OPuS”) 270 and an autoshutter, in this case a combined autoshutter metrology module (“CASMM”) 275, which may also be the location of a pulse energy meter. One purpose of the OPUS 270 may be, e.g., to convert a single output laser pulse into a pulse train. Secondary pulses created from the original single output pulse may be delayed with respect to each other. By distributing the original laser pulse energy into a train of secondary pulses, the effective pulse length of the laser can be expanded and at the same time the peak pulse intensity reduced. The OPUS 270 may accordingly be arranged to receive the laser beam from the PRA WEB 255 and direct its output to the CASMM 275.

The beam path through the BR 260, the PA discharge chamber 250, and the BAM 265 defines an optical axis 267 for each of these components.

The PRA discharge chamber 250 and the MO discharge chamber 220 are configured as chambers in which electrical discharges between the electrodes cause lasing gas discharges in a lasing gas to create an inverted population of high energy molecules or excimers, including, e.g., ArF, KrF, F₂, XeF, and/or XeCl, to produce relatively broad band radiation that may be line narrowed to a relatively very narrow bandwidth and center wavelength selected in the LNM 235.

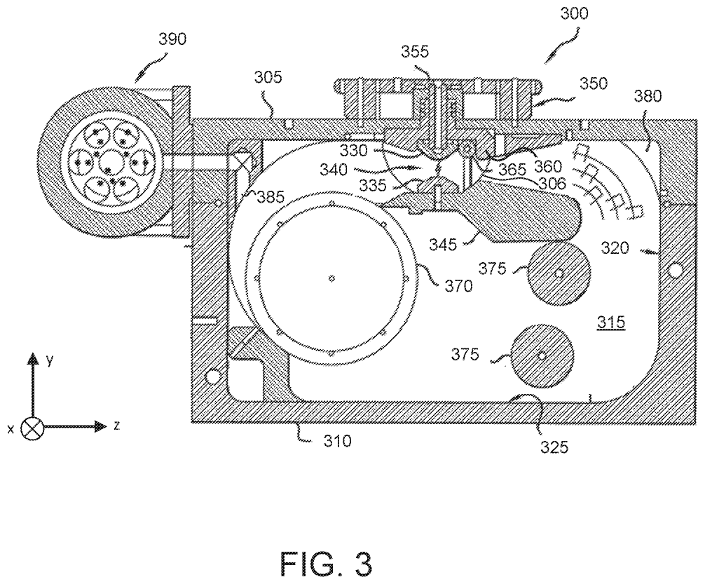

Turning now to FIG. 3 there is shown a laser discharge chamber 300 which may serve, for example, as the PRA discharge chamber 250 or the MO discharge chamber 220. The chamber 300 may be composed, e.g., of an upper chamber body 305 and a lower chamber body 310, which may, when connected to each other by suitable means, e.g., by bolting, serve to define a chamber interior 315. The upper chamber body 305 and lower chamber body 310 also define a chamber interior vertical wall 320 with the lower chamber body 310 defining a chamber interior horizontal bottom wall 325.

In this specification including the claims the terms “up,” “down,” “upper,” “lower,” “top,” “bottom,” “vertical,” “horizontal,” and like terms are intended to connote relative orientation only and not any absolute orientation such as orientation with respect to gravity unless otherwise indicated or clear from context.

Contained within the chamber interior 315 is, e.g., a gas discharge system comprising two elongated (along the X axis out of the plane of the figure) opposing electrodes, a cathode 330 and an anode 335, defining between them an elongated gas discharge gap or region 340, wherein, in response to a sufficient voltage being imposed across the cathode 330 and anode 335, a discharge occurs in the gas discharge region 340 resulting in the production of radiation at or near a characteristic center wavelength, that is optically directed along the optical axis of the output laser radiation pulse generally aligned to the longitudinal optical axis of the laser discharge chamber 300 along the X axis (out of the plane of the figure) as indicated by the inset.

Also within the chamber interior 315 may be, e.g., an anode support bar 345. The anode 335 may be electrically connected to the upper chamber body 305 through a plurality of current returns 306, with the upper chamber body 305, along with lower chamber body 310, being kept at a common voltage, e.g., at ground voltage.

The cathode 330 may, e.g., be connected to an electrical discharge high voltage feed through an assembly 350, e.g., by a high voltage feed through 355, which passes through a main insulator 360. The main insulator 360 may keep the cathode 330 electrically isolated from the upper chamber body 305. Also within the chamber interior 315 may be, e.g., a preionizer 365, which may include, for example, a preionizer tube, adjacent the cathode 330. The preionizer 365 may be configured as an elongate hollow, tube made of dielectric material that is aligned parallel to the discharge electrodes and positioned near the discharge region. A conductive preionization electrode (typically made of copper or brass), is positioned in the bore of the tube and used to create a potential difference between the preionization electrode and one of the main discharge electrodes. This potential difference extends across the dielectric tube radially and results in a substantially uniform emission of photons that are emitted from the outer surface of the tube.

More information about preionizers may be found in U.S. Pat. No. 7,542,502, titled “Thermal-expansion Tolerant, Preionizer Electrode for a Gas Discharge Laser,”, issued Jun. 2, 2009.

All patent applications, patents, and printed publications cited herein are incorporated herein by reference in their entireties, except for any definitions, subject matter disclaimers, or disavowals, and except to the extent that the incorporated material is inconsistent with the express disclosure herein, in which case the language in this disclosure controls.

Also within the chamber interior 315 may be a gas circulation system comprising a gas circulation fan 370, which may be, e.g., a generally cylindrical crossflow fan 370. The fan 370 serves to move gas within the chamber interior 315, generally in a circular fashion as seen in the cross-sectional view of FIG. 3, in order to remove gas that contains ionized particles and debris and is depleted of F₂ from the discharge region 340 between successive discharges, and thus to replenish the discharge region 340 with fresh gas before the next gas discharge. The gas circulation system may also include a plurality of heat exchangers 375 in the generally circular gas flow path to remove heat added to the gas, e.g., by the discharges and the operation of the fan 370.

The gas circulation system may also have a plurality of curved baffles 380 and a flow directing vane 385, which may serve to shape the generally circular gas flow path out of the discharge region 340 toward the heat exchangers 375 and ultimately the intake of the fan 370, and from the output of the fan 370 to the discharge region 340, respectively. The upper chamber body 305 may also have an attached metal fluoride trap 390 in fluid communication with the chamber interior 315.

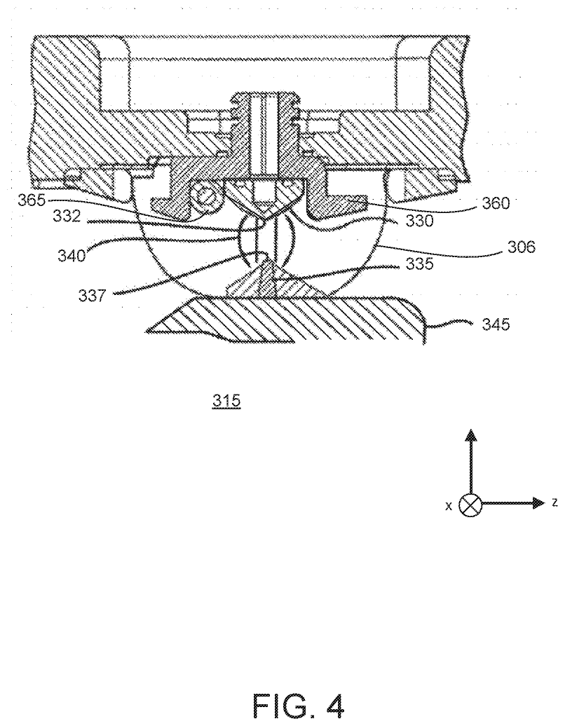

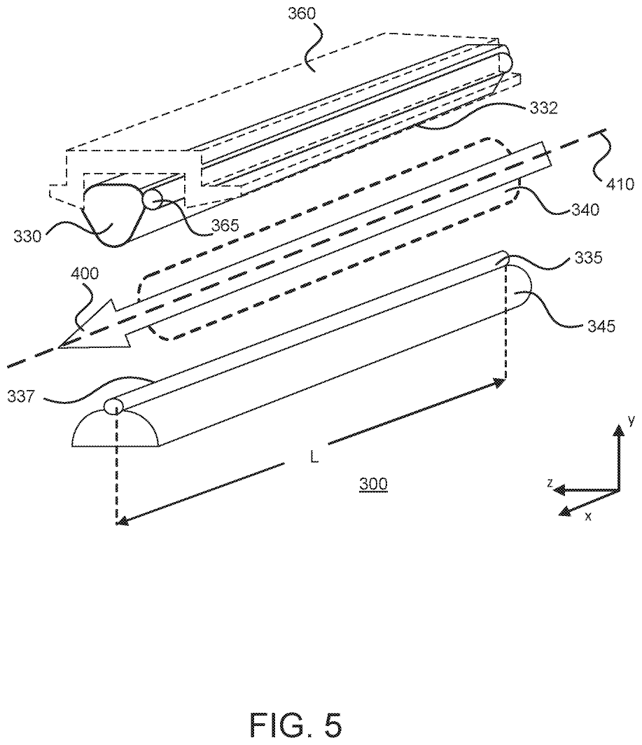

FIG. 4 is a schematic view that further illustrates how the electrodes and adjacent components are situated in the gas discharge laser chamber. As shown in FIG. 4, anode 335 and cathode 330 are disposed in an opposing relationship so that elongated cathode discharge surface 332 faces elongated discharge anode surface 337. Anode 335 is mounted on an anode support bar 345. Gas discharge region 340, which is the space defined between elongated cathode discharge surface 332 and elongated anode discharge surface 337, typically has a height (direction of the Y axis) of about 0.5 inch. In one example, the length L (see FIG. 5) of each of the anode 335 and the cathode may for example lie in a range of about 20 inches to 30 inches. As noted above, the width of the discharge area and the length of the electrodes may be varied to suit the needs of particular applications. Also visible in FIG. 4 is preionizer 365.

FIG. 5 is a perspective view of an example of the arrangement of components in the laser discharge chamber 300. As can be seen in FIG. 5, the elongate cathode discharge surface 332 of the cathode 330 faces an elongate anode discharge surface 337 of the anode 335 across a gap defining the discharge region 340. When a discharge occurs in the discharge region 340, radiation generated by the discharge propagates in the direction indicated by arrow 400. Also shown is an optical axis 410 for the laser discharge chamber 300. As depicted, the optical axis 410 may be regarded as extending parallel to an X axis of a right-handed cartesian coordinate system. The elongate cathode 330, the elongate anode 335, and the gap defining the discharge region 340 all extend parallel to the optical axis 410. Also visible in FIG. 5 is preionizer 365 which also extends parallel to the optical axis 410. FIG. 5 also shows in phantom the main insulator 360 which also extends parallel to the optical axis 410. Also visible in FIG. 5 is the anode support bar 345 which also extends parallel to the optical axis 410.

The discharge occurring in the discharge region 340 generates acoustic waves inside the discharge chamber 300. The acoustic waves generated by the discharge propagate outward from the discharge region 340, reflect off of internal surfaces of the laser discharge chamber 300, and then return to the discharge region where they distort the laser beam produced by subsequent pulses.

One measure that may be employed to mitigate the adverse effects of these acoustic disturbances involves arranging acoustic baffles on the internal surfaces of the walls of the discharge chamber. As a result acoustic waves that are reflected by the walls do not return to the discharge region all at once in a coherent fashion. Rather the baffles randomize, i.e., scatter acoustic reflections. This mitigates resonance reflections because the return waves arrive at different parts of the discharge region at different times, reducing their overall adverse effect on laser performance. This measure is in general effective to suppress resonances at 4 kHz and below, but at higher repetition rates the reflecting surfaces that affect performance most significantly are located closer to, and above and below, the discharge region, rather than located at a distance laterally displaced at a greater distance from the discharge region.

The potential for distortion is thus the most significant when the acoustic wave returns at a time coinciding with the start of a new discharge. Thus the amount of distortion in general depends on the relationship between the repetition rate of the pulses and the round trip time-of-flight distance of acoustic waves travelling at the speed of sound from the discharge area to reflecting surfaces within the laser discharge chamber and back again. At higher repetition rates, for example, in the range of 5.8 kHz to 6 kHz, the reflecting surfaces more proximate to the discharge area 340 dominate the resonant acoustic distortion effect. These include surfaces above and below the discharge region such as surfaces of the preionizer, the main insulator, and the anode support bar facing the discharge region.

As mentioned, the preionizer is characteristically configured as an electrode arranged in a cylindrical tube made of a dielectric material such as a ceramic material. The preionizer tube typically has a smooth external surface that gives rise to the type of coherent acoustic reflections that can lead to resonances in laser performance characteristics (e.g. bandwidth) at higher repetition rates, e.g., repetition rates near or in excess of 6 kHz.

In accordance with an aspect of an embodiment, at least part of the surface of the preionizer tube is engineered by providing it with acoustic scattering features that function as acoustic baffles that interact with acoustic waves impinging on the surface by scattering the acoustic waves, essentially randomizing the reflected waves so they do not return to the discharge region in a coherent fashion. The acoustic scattering features are provided on at least the part of the exterior surface of the preionizer tube that will be arranged to face the discharge region although it will be understood that the acoustic scattering features may also be provided on other parts, including the entirety, of the exterior surface of the tube. In the specification, including the claims, the surface on which the acoustic scattering features are provided is referred to as the acoustic scattering surface. Herein, “provided with” is intended to refer to processes such as molding that create the acoustic scattering features during manufacture of the preionizer tube as well as processes that add the acoustic scattering features to the wall/exterior surface of the preionizer tube after manufacture of the preionizer tube.

The acoustic scattering features can be created by any one of a number of possible methods. For example, the acoustic scattering features may be implemented by molding the material making up the preionizer tube so that its surface includes the acoustic scattering features. As another example, the acoustic scattering features may be machined out of the exterior of the wall of the preionizer tube using a cutting tool. Other methods including placing a layer of material on the exterior wall of the preionizer tube where the layer is provided with the acoustic scattering features may be used.

It will be appreciated by one of ordinary skill in the art that various parameters relating to the acoustic scattering features such as their shape, depth, area, distribution (including spacing), percent surface coverage, and density (number of features per unit area) be varied according to the considerations of a particular application. For example, as for depth, it may be assumed that the range of acoustic wavelengths of interest is defined by the physical size (width and height) of the cross section of the laser discharge. Effects from acoustic waves having wavelengths much smaller than the discharge cross section can be assumed to average to zero. In addition, acoustic waves having wavelengths much larger than the discharge cross section can be assumed to create a pressure gradient that is insufficient to have a significant adverse effect on laser performance.

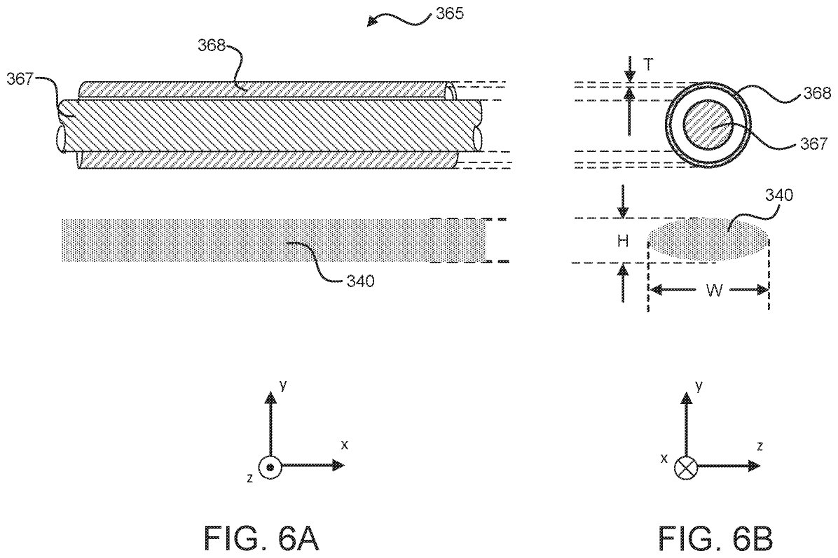

FIG. 6A is a not-to-scale cross section of part of the length of a preionizer tube wall 368 and electrode 367 with respect to a discharge region 340. FIG. 6B is an end-on view of the preionizer tube wall 368 and electrode 367 of FIG. 6A. A typical discharge in the discharge region 340 in an ArF excimer laser may have a cross section that is approximately 2 mm (0.079″) high (dimension H in FIG. 6B) by 14 mm wide (0.551″) (dimension W in FIG. 6B). Applying the acoustic quarter wavelength rule, the acoustic scattering feature should be at least as large as one-quarter of the acoustic wavelengths in this range and so an exemplary range for a depth of the acoustic scattering features is about 0.02″ to about 0.14″.

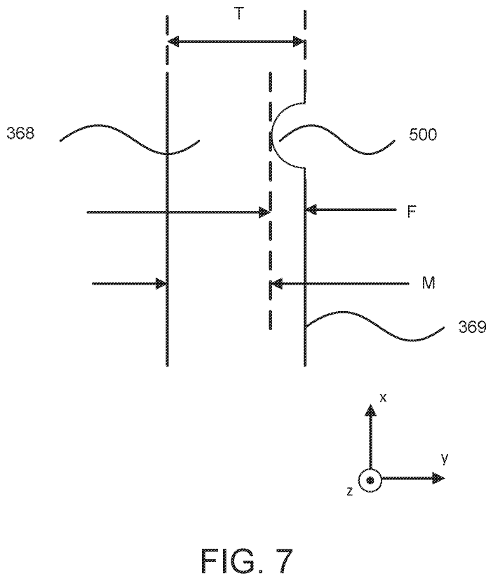

FIG. 7 is a cross section of a lengthwise portion of the preionizer tube wall 368 with an acoustic scattering feature 500. As shown in FIG. 7, as well as in FIG. 6B, the preionizer tube wall 368 may have a nominal thickness, for example, in a range of about 0.150 inches to 0.3 inches. Herein, nominal thickness refers to the thickness in areas having no acoustic scattering features. This is shown as dimension T in FIG. 6B and FIG. 7. A given application may require that the preionizer tube wall thickness at all locations must be, for example, at least 0.125 inches. For a preionizer tube wall with a nominal thickness T of 0.190 inches, for example, the maximum depth (extent F beneath the exterior surface 369 of, and into, the preionizer tube wall 368) of the acoustic scattering feature 500 can be no more than 0.065 inches if a minimum thickness M of 0.125 inches is to be preserved. This depth is more than enough to accommodate effective acoustic scattering features based on the design considerations stated above. In some embodiments the acoustic scattering features have a depth into the preionizer tube wall 368 greater than one half the nominal thickness of the preionizer tube wall 368.

It will be noted that the cross section of the example of an acoustic scattering feature 500 as depicted in FIG. 7 is semicircular with the acoustic scattering feature 500 itself being realized as a hemispherical depression or cavity in the surface of, and into the wall of, the preionizer tube. It will be appreciated that other shapes may be used as described more fully below.

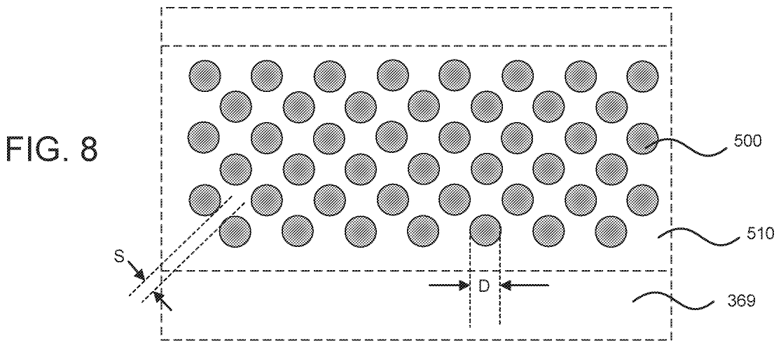

FIG. 8 is a projection of a portion of the exterior surface 369 of the preionizer tube wall 368 provided with acoustic scattering features 500 to create an acoustic scattering surface 510. In general the acoustic scattering surface 510 is provided on at least that portion of the exterior surface 369 that will be arranged to face the discharge region 340 (FIG. 5) and so will receive and reflect acoustic waves from discharges in the discharge region 340. It may in some circumstances be desirable based on considerations such as ease of manufacturing, installation, and maintenance to provide the entire exterior surface 369 with acoustic scattering features 500.

In the embodiment depicted in FIG. 8 the acoustic scattering features 500 are arranged in a periodic array with an edge-to-edge spacing of the acoustic scattering features 500 with their nearest neighbor being labeled S and a size of each of the acoustic scattering features 500 being labeled D. In general it is desirable to make S small because the greater S is then the greater the amount of flat surface will be available to reflect acoustic waves. In some embodiments S will preferably be in a range of 0.1 inches to 0.5 inches. The range for the dimension D will in general coincide with the range defined above as being relevant to acoustic reflections. Thus D in some embodiments will preferably be in a range of 0.1 inches to 0.3 inches. In some embodiments S and D are selected to cover a percentage of the acoustic scattering surface 510 in a range of 10 percent to 100 percent. In some embodiments the acoustic scattering features may have a density in a range of 3 acoustic scattering features per square inch to 100 acoustic scattering features per square inch.

In the embodiment of FIG. 8 the acoustic scattering features 500 are again shown as hemispherical depressions or cavities. It will again be appreciated other shapes may be used. Also, in the embodiment of FIG. 8 all of the acoustic scattering features 500 are of the same size and shape. One of ordinary skill will appreciate that the acoustic scattering features 500 may be of different sizes and shapes.

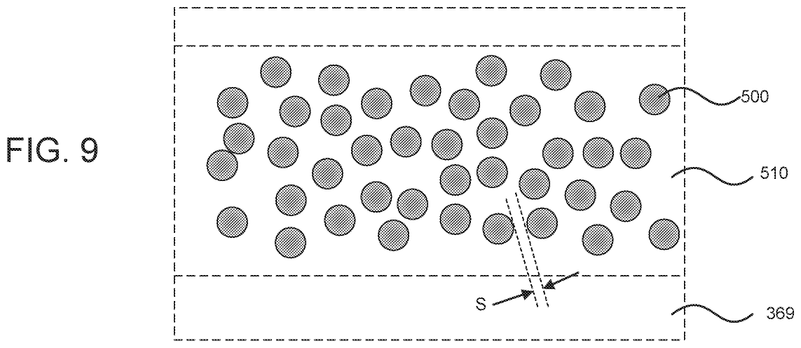

In the embodiment of FIG. 8 the acoustic scattering features 500 are arranged in a regular array. The acoustic scattering features 500 may alternatively be positioned randomly in an irregular or aperiodic array as shown in FIG. 9. In the embodiment of FIG. 9 the acoustic scattering features 500 are once again shown as hemispherical depressions or cavities. It will again be appreciated that other shapes may be used. Also, in the embodiment of FIG. 9 all of the acoustic scattering features 500 are again all of the same size and shape. One of ordinary skill will appreciate that at least some of the acoustic scattering features 500 may differ from others in size and shape.

One of ordinary skill in the art will appreciate that the acoustic scattering features may be created or placed on the preionizer tube in arrangements other than those just described as long as the acoustic scattering features serve the purpose of redirecting acoustic waves in directions other than coherently back towards the subregion of the discharge from which they originated. For example, the acoustic scattering features may be arranged as a linear series of baffles along the longitudinal axis of the preionizer tube. For example, FIG. 10 is a side view of a preionizer 365 with acoustic scattering features 500 arranged so that a portion of the surface extending in the axial direction has series of triangular features with one side of the triangle extending in a radial direction with respect to the preionizer 365. FIG. 11 is a perspective view of the preionizer tube 366 of FIG. 10.

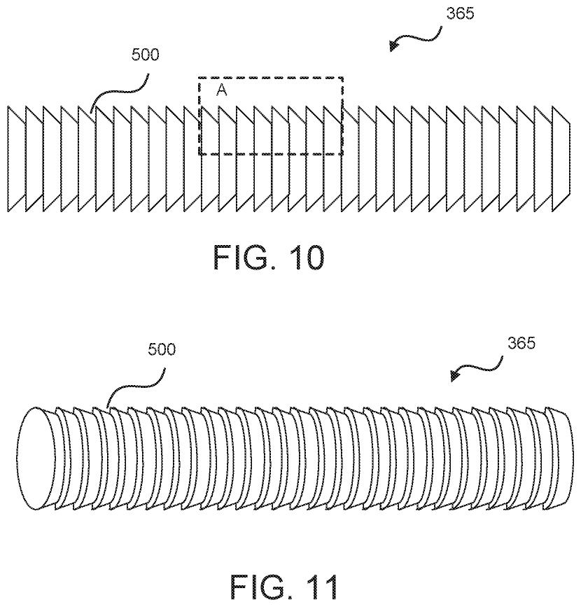

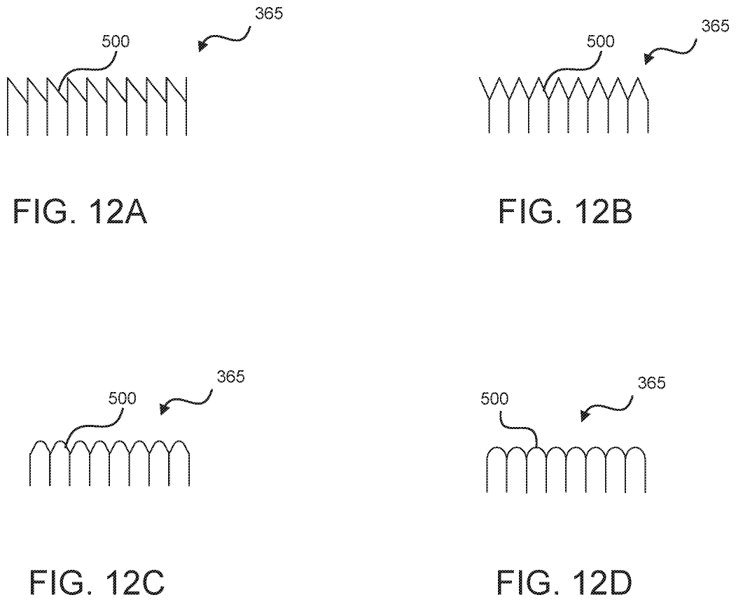

The shape of the acoustic scattering features 500 may also vary. FIG. 12A is a magnified view of the portion of the preionizer tube 366 within dotted box A in FIG. 11. As noted above, the acoustic scattering features 500 are implemented as a line of triangular features with one side of the triangle being arranged parallel to a radius of the preionizer tube of preionizer 366. FIG. 12B shows another arrangement of acoustic scattering features 500 in which each of the triangles has an outwardly pointing vertex at an angle less than 45 degrees and both sides of the triangle are oriented at an angle with respect to the radial direction of the preionizer tube. FIG. 12C depicts an embodiment in which the acoustic scattering features 500 have a rounded shape projecting out from the surface of the preionizer tube. FIG. 12D depicts an embodiment in which each of the acoustic scattering features has a substantially semicircular projection. One of ordinary skill in the art will readily appreciate that other shapes may be used. Also, in the embodiments just described, the acoustic scattering features 500 are all of the same general shape and dimensions. One of ordinary skill in the art will readily appreciate that some of the acoustic scattering features 500 may have shapes and dimensions that are different from the shapes and dimensions of others of the acoustic scattering features 500.

It will be appreciated that acoustic scattering features on the surface of the preionizer tube wall comprise an engineered surface having local deviations from two dimensional planarity so that the acoustic scattering features have height and/or depth and can equivalently be regarded extending into and out of the preionizer tube wall or into and out of the preionizer tube wall surface.

In addition or alternatively to the mitigation measures described above, according to another aspect of an embodiment, at least part of the preionizer tube is configured to present an angled surface to the discharge region, for example, by having a tapering instead of a cylindrical transverse cross section. Thus, when the preionizer tube is installed in the chamber at least some surfaces of the preionizer tube do not reflect acoustic waves from the discharge region back to their origin in a coherent fashion. The preionizer tube may have any shape which accomplishes this end including a frustoconical (truncated cone) shape, two truncated cones set with large diameter to large diameter or small diameter to small diameter (complex quadrilateral (bowtie) shape), or a surface of revolution such as a hyperboloid.

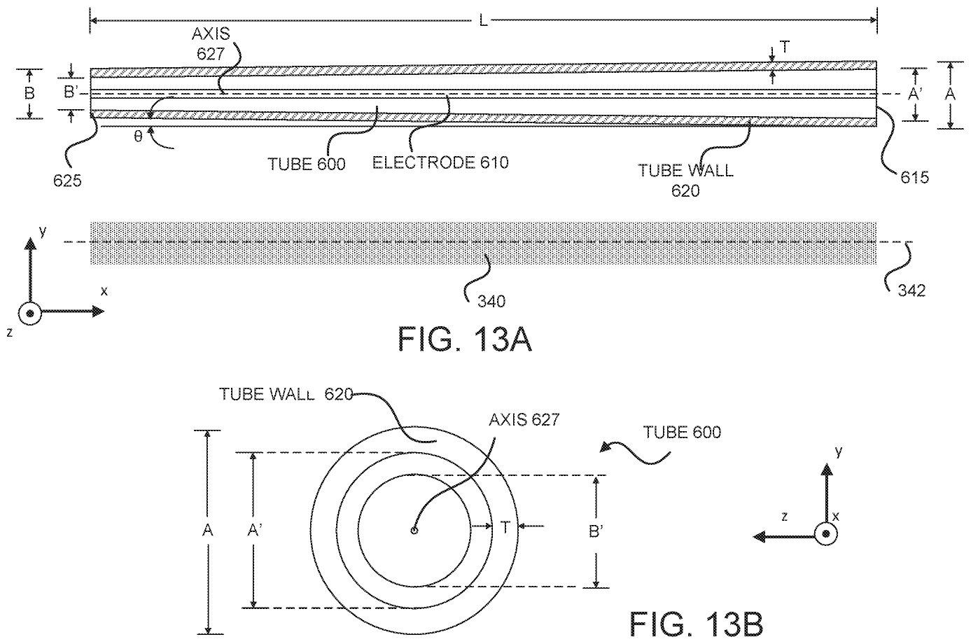

FIGS. 13A and 13B show a preionizer tube 600 in accordance with an aspect of an embodiment. The preionizer tube 600 contains an electrode 610. The preionizer tube 600, however, is not configured as a cylinder. Instead, the preionizer tube 600 is tapered from one end 615 to the other end 625. The preionizer tube 600 has a circular transverse cross section as shown in FIG. 13B with an axis of symmetry 627. While the axis of symmetry 627 of the preionizer tube 600 will in general be parallel to the optical axis 342 of the discharge region 340, the preionizer tube wall 620 will be disposed at a nonzero angle to the optical axis 342 of the discharge region 340.

The end 615 has an outside diameter A and the end 625 has an outside diameter B, with B being less than A. Thus the outside diameter of the preionizer tube 600 decreases linearly from A to B over the length L of the preionizer tube 600 to form a preionizer tube in the shape of a truncated cone, i.e., which is frustoconical. As a result of the taper, the surface of the preionizer tube wall 620 makes an angle θ with the discharge region 340. The magnitude of the angle θ will depend on the magnitude of the outside diameter A, the magnitude of the outside diameter B, and the length L of the preionizer tube 600. In general,

$$θ = {tan}^{- 1} \frac{( A - B )}{2 L}$$

The magnitude of the angle θ may be in the range, for example, of about 0.2° to about 2°. A smaller angle θ may not sufficiently redirect the acoustic waves from the discharge region. A larger angle θ could start to have a detrimental effect on the functioning of the preionization tube and require rearrangement of components within the chamber without making a significant additional contribution to resonance reduction.

The dimensions of the preionizer tube 600 will in general be dictated by the requirements of a particular application. For some implementations, it may be beneficial to have the outside diameter of one of the ends 615, 625 of the preionizer tube 600 be the same as the outside diameter of a conventional cylindrical preionizer tube. This could assist in the installation of the preionizer tube 600 and in retrofitting chambers that are already deployed in the field. For some implementations, it may be advantageous to maintain the outer diameter of the preionizer tube 600 so that it remains shielded from gas flows by surrounding structures such as the main insulator 360 (FIG. 4). It should be noted in this context, however, that the main insulator can be redesigned to accommodate preionizer tubes having larger diameters. In general, the outside diameter A may be in the range of about 0.25 inches to about 1 inch. The smaller outside diameter B may also have a diameter in the range of about 0.25 inches to about 0.95 inches, with B being maintained less than A.

According to another aspect of an embodiment, and as shown in FIGS. 13A and 13B, the inner diameter A′ of the preionizer tube 600 at the end 615 may be larger than the inner diameter B′ of the preionizer tube 600 at the end 625 to permit maintaining a more uniform thickness T of the wall 620 of the preionizer tube 600.

Thus, the preionizer tube 600 is configured as an elongated hollow tube having a first end 615, a second end 625, and the axis of circular symmetry 627 extending along a length of the preionizer tube 600 from a center of the first end 615 to a center of the second end 625 with an outside diameter of at least a lengthwise section of the elongated hollow tube varying (e.g., increasing or decreasing) linearly as a function of longitudinal (measured along the length L) distance from the first end 615. The lengthwise section may extend the entire length L of the preionizer tube 600 as shown or may extend only part of the length L of the preionizer tube 600.

According to another aspect of an embodiment, a preionizer tube 600 such as that depicted in FIGS. 13A and 13B may be fabricated using a two-piece electrode with the two pieces having different diameters in order to fit into respective preionizer tube sockets of differing diameters at each end. The preionizer tube 600 could also be fabricated by machining a ceramic material or molding and then hardening a ceramic material, depending on the particular application.

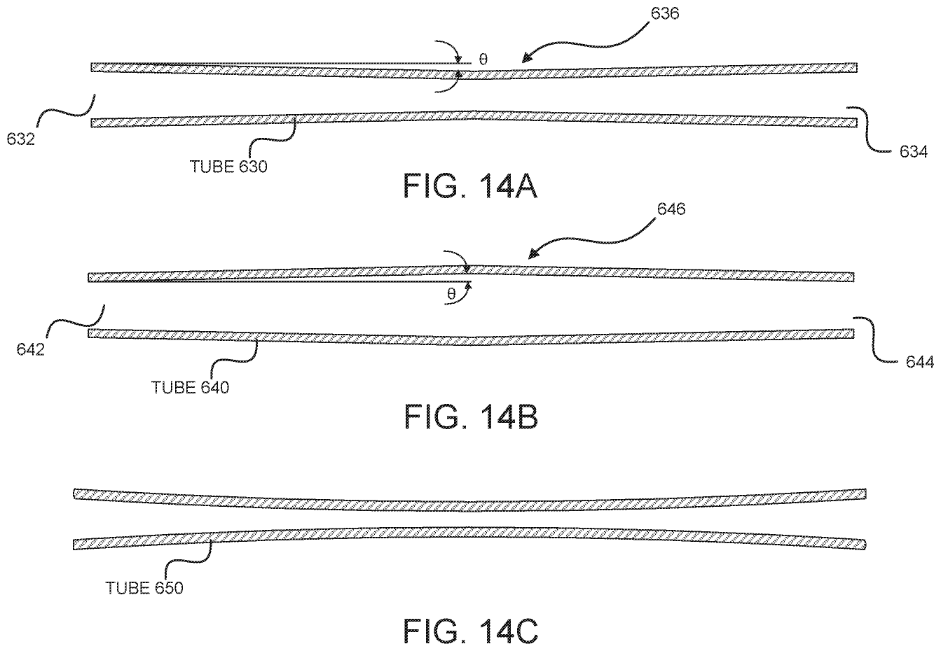

The preionizer tube could have shapes other than frustoconical so long as the goal of having surfaces that are not parallel to the longitudinal optical axis of the discharge region is met. FIG. 14A shows a configuration for a preionizer tube 630 having a generally bowtie configuration with its two ends 632, 634 having the same outside diameter and the middle portion 636 being pinched to a smaller outside diameter.

FIG. 14B shows a preionizer tube 640 in the form of two truncated cones set large diameter end to large diameter with the two small ends 642, 644 having the same outside diameter but where the middle portion 646 has an expanded outside diameter causing the preionizer tube 640 to present angled surfaces to the discharge region. FIG. 14C shows a preionizer tube 650 formed by a surface of rotation, for example, a hyperbola to form a hyperboloid, to form surfaces which are not parallel to the discharge region. It will be apparent to one of ordinary skill in the art that the two ends for any of these embodiments do not necessarily have to have the same outside diameter. It will also be apparent of one of ordinary skill in the art that other configurations with uneven surfaces are possible.

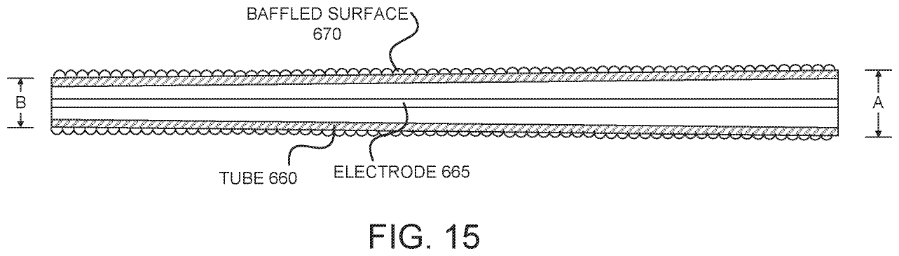

In the foregoing embodiments, the preionizer tube may have a conventional unstructured surface. As stated above, however, the preionizer tube may have both structured or engineered (e.g., acoustically baffled) surface and a tapering transverse cross section. FIG. 15 shows an example of such a tapered and baffled preionizer tube 660 which is provided with a structured surface 670. The structured surface 670 may be of any of the types described above. A preionizer tube 660 of the configuration of FIG. 15 thus employs multiple measures to redirect acoustic energy so that it is not simply reflected back into the portion of the discharge region which generated it.

Some of the above description is in terms of functional block diagrams with some functions allocated to some blocks and other functions allocated to other blocks. It will be understood that the division between blocks and the allocations are arbitrary and that different divisions and allocations are possible so long as the overall functions are carried out as described above.

The above description includes examples of multiple embodiments. It is, of course, not possible to describe every conceivable combination of components or methodologies for each of these embodiments, but one of ordinary skill in the art may recognize that many further combinations and permutations of elements of the various embodiments are possible based on the disclosure. Accordingly, the described embodiments are intended to be representative of and encompass all such alterations, modifications, and variations that fall within the spirit and scope of the appended claims.

Furthermore, to the extent that the term “includes” is used in either the detailed description or the claims, such term is intended to be inclusive in a manner similar to the term “comprising” as “comprising” is construed when employed as a transitional word in a claim. Also, although elements of the described aspects and/or embodiments may be described or claimed in the singular, the plural is contemplated unless limitation to the singular is explicitly stated. Additionally, all or a portion of any aspect and/or embodiment may be utilized with all or a portion of any other aspect and/or embodiment, unless stated otherwise.

Aspects and implementations of the present disclosure can be further described using the following clauses:

1. A preionizer for a laser system, the preionizer comprising:
a tube configured as a generally cylindrical hollow tube extending axially in a first direction and having a tube wall with an outer surface, at least a portion of the outer surface being provided with a plurality of acoustic scattering features; and
an electrode positioned at least partially within the tube.
   2. The preionizer as in clause 1, wherein the tube comprises a dielectric material.
   3. The preionizer as in clause 1, wherein the acoustic scattering features have a depth into the tube wall greater than one half the nominal thickness of the tube wall.
   4. The preionizer as in clause 1, wherein the laser system operates at 6 kHz and the acoustic scattering features have depths into the tube wall of at least 0.063 inches.
   5. The preionizer as in clause 1, wherein the laser system is configured to generate a discharge in a discharge region having a height H and a width W and wherein a depth of the acoustic scattering features into the tube wall is in a range between ¼ H and ¼ W, inclusive.
   6. The preionizer as in clause 1 wherein the laser system is configured to generate a discharge in a discharge region and wherein the acoustic scattering features are provided on at least a portion of the outer surface arranged to face the discharge area.
   7. The preionizer as in clause 1 wherein the acoustic scattering features are provided on substantially all of the outer surface.
   8. The preionizer as in clause 1 wherein the acoustic scattering features are made by molding the acoustic scattering features into the at least a portion of the outer surface.
   9. The preionizer as in clause 1 wherein the plurality of acoustic scattering features are arranged in an array provided on the at least a portion of the outer surface.
   10. The preionizer as in clause 9 wherein the array is aperiodic.
   11. The preionizer as in clause 1 wherein nearest ones of the plurality of acoustic scattering features are spaced apart edge-to-edge by distances in a range from 0.01 inches to 0.5 inches.
   12. The preionizer as in clause 1 wherein the acoustic scattering features are arranged to have a density in a range of 3 acoustic scattering features per square inch to 100 acoustic scattering features per square inch.
   13. The preionizer as in clause 1 wherein the plurality of acoustic scattering features includes acoustic scattering features respectively having areas in a range of 0.1 square inches to 0.5 square inches.
   14. The preionizer as in clause 1 wherein the plurality of acoustic scattering features collectively have a percent coverage of the outer surface in a range of 10 percent to 100 percent.
   15. A preionizer for an excimer laser, the preionizer comprising:
a tube body having a tube wall, the tube wall having an external surface;
a plurality of baffles provided on an acoustic scattering surface of the external surface, the acoustic scattering surface extending lengthways along a length of the tube body, each of the baffles being arranged and dimensioned to scatter acoustic reflections from the acoustic scattering surface; and
an electrode positioned at least partially within the tube body.
   16. The preionizer as in clause 15, wherein the tube wall comprises a dielectric material.
   17. The preionizer as in clause 15, wherein the baffles have a depth into the tube wall that is greater than one half the thickness of the tube wall.
   18. The preionizer as in clause 15, wherein the excimer laser operates at 6 kHz and wherein the baffles have depths into the tube wall of at least 0.063 inches.
   19. The preionizer as in clause 15, wherein the excimer laser is configured to generate a discharge in a discharge region having a height H and a width W and wherein a depth of the baffles into the tube wall is in a range between ¼ H and ¼ L, inclusive.
   20. The preionizer as in clause 15 wherein the excimer laser is configured to generate a discharge in a discharge region and wherein the acoustic scattering surface comprises a portion of the external surface facing the discharge area.
   21. The preionizer as in clause 15 wherein the acoustic scattering surface comprises substantially all of the external surface.
   22. The preionizer as in clause 15 wherein the acoustic scattering surface is made by molding the baffles into the tube wall.
   23. The preionizer as in clause 15 wherein the acoustic scattering surface comprises an array of baffles provided on the external surface.
   24. The preionizer as in clause 23 wherein the array is aperiodic.
   25. The preionizer as in clause 15 wherein the plurality of baffles are arranged to have a density in a range of 3 baffles per square inch to 100 baffles per square inch.
   26. The preionizer as in clause 15 wherein the plurality of baffles includes baffles respectively having areas in a range of 0.1 square inches to 0.5 square inches.
   27. The preionizer as in clause 15 wherein the baffles have a nearest neighbor edge-to-edge spacing in a range of 0.01 inches to 0.5 inches.
   28. The preionizer as in clause 15 wherein the plurality of baffles cover 10 percent to 100 percent of the external surface.
   29. A discharge chamber for a laser system, the discharge chamber comprising:
a first electrode having a first electrode discharge surface;
a second electrode having a second electrode discharge surface, the first electrode discharge surface being arranged facing and spaced away from the second electrode discharge surface to define a discharge gap; and
a preionizer including a preionizer tube extending laterally adjacent the first electrode, a surface of the preionizer tube facing the discharge gap being provided with a plurality of acoustic scattering features dimensioned and arranged to scatter acoustic waves from the discharge gap.
   30. The discharge chamber as in clause 29, wherein the preionizer tube comprises a dielectric material.
   31. The discharge chamber as in clause 29, wherein the acoustic scattering features have a depth into the preionizer tube facing the discharge gap, that is greater than one half the nominal thickness of a wall of the preionizer tube.
   32. The discharge chamber as in clause 29, wherein the discharge chamber operates at 6 kHz and the acoustic scattering features have depths into the preionizer tube of at least 0.063 inches.
   33. The discharge chamber as in clause 29 wherein the discharge chamber is configured to generate a discharge in a discharge region having a height H and a width W and wherein a depth of the acoustic scattering features into the preionizer tube is in a range between ¼ H and ¼ W, inclusive.
   34. The discharge chamber as in clause 29 wherein the acoustic scattering surface is made by molding the acoustic scattering features into a wall of the preionizer tube.
   35. The discharge chamber as in clause 29 wherein the acoustic scattering surface comprises an array of acoustic scattering features provided on the surface of the preionizer tube facing the discharge gap.
   36. The discharge chamber as in clause 35 wherein the array is aperiodic.
   37. The discharge chamber as in clause 29 wherein the respective acoustic scattering features are spaced apart edge-to-edge from a nearest acoustic scattering structure by distances in a range from 0.01 inches to 0.5 inches.
   38. The discharge chamber as in clause 29 wherein the acoustic scattering features are arranged to have a density on the surface of the preionizer tube facing the discharge gap in a range of 3 acoustic scattering features per square inch to 100 acoustic scattering features per square inch.
   39. The discharge chamber as in clause 29 wherein the plurality of acoustic scattering features includes acoustic scattering features respectively having areas in a range of 0.1 square inches to 0.5 square inches.
   40. The discharge chamber as in clause 29 wherein the acoustic scattering features cover about 10 percent to 100 percent of the surface of the preionizer tube facing the discharge gap.

The above-described aspects and implementations and other implementations are within the scope of the following claims.

1. A preionizer for a laser system, the preionizer comprising:
a tube configured as a generally cylindrical hollow tube extending axially in a first direction and having a tube wall with an outer surface, at least a portion of the outer surface being provided with a plurality of acoustic scattering features; and
an electrode positioned at least partially within the tube.

2. The preionizer as in claim 1, wherein the tube comprises a dielectric material.

3. The preionizer as in claim 1, wherein the acoustic scattering features have a depth into the tube wall greater than one half the nominal thickness of the tube wall.

4. The preionizer as in claim 1, wherein the laser system operates at 6 kHz and the acoustic scattering features have depths into the tube wall of at least 0.063 inches.

5. The preionizer as in claim 1, wherein the laser system is configured to generate a discharge in a discharge region having a height H and a width W and wherein a depth of the acoustic scattering features into the tube wall is in a range between ¼ H and ¼ W, inclusive.

6. The preionizer as in claim 1 wherein the laser system is configured to generate a discharge in a discharge region and wherein the acoustic scattering features are provided on at least a portion of the outer surface arranged to face the discharge area.

7. (canceled)

8. (canceled)

9. The preionizer as in claim 1 wherein the plurality of acoustic scattering features are arranged in an array provided on the at least a portion of the outer surface.

10. The preionizer as in claim 9 wherein the array is aperiodic.

11. The preionizer as in claim 1 wherein nearest ones of the plurality of acoustic scattering features are spaced apart edge-to-edge by distances in a range from 0.01 inches to 0.5 inches.

12. The preionizer as in claim 1 wherein the acoustic scattering features are arranged to have a density in a range of 3 acoustic scattering features per square inch to 100 acoustic scattering features per square inch.

13-40. (canceled)

41. A preionizer for a laser system, the preionizer comprising:
an elongated hollow tube having a first end, a second end, and an axis of circular symmetry extending along a length of the tube from a center of the first end to a center of the second end with an outside diameter of at least a lengthwise section of the elongated hollow tube varying from the first end; and
an electrode positioned at least partially within the elongated hollow tube.

42. The preionizer of claim 41 wherein the lengthwise section comprises an entire length of the elongated hollow tube.

43. The preionizer of claim 41 wherein the outside diameter of the lengthwise section increases linearly as a function of longitudinal distance from the first end.

44. The preionizer of claim 41 wherein the outside diameter of the lengthwise section decreases linearly as a function of longitudinal distance from the first end.

45. The preionizers of claim 41 wherein at least a portion of an outer surface of the elongated hollow tube has a plurality of acoustic scattering features.

46. (canceled)

47. A method for scattering acoustic waves in a discharge chamber comprising:
generating a pulsed radiation beam in a discharge region;
generating acoustic waves outward from the discharge region; and
scattering the acoustic waves from an acoustic scattering feature on an at least a portion of an outer surface of a preionizer tube, wherein the acoustic scattering feature is arranged in an array provided on the at least a portion of the outer surface.

48. The method of claim 47, wherein scattering the acoustic waves includes randomizing the acoustic waves reflected from the at least a portion of the outer surface of the preionizer tube.

49. The method of claim 47, wherein scattering the acoustic waves includes preventing the acoustic waves being reflected from the discharge region back to their origin in a coherent fashion.

50. The method of claim 47, wherein the acoustic scattering feature is at least as large as one-quarter of a wavelength of the acoustic waves.

51. The method of claim 47, wherein the discharge chamber operates at about 6 kHz and the acoustic scattering feature has a depth into the preionizer tube wall of at least about 0.063 inches.
